(19) United States
(12) Patent Application Publication
(10) Pub. No.: US 2026/0231818 A1
(43) Pub. Date: Aug. 6, 2026

(54) MICROELECTRONIC DEVICE PACKAGE WITH INTEGRATED TRENCH CAPACITOR DIES AND SEMICONDUCTOR DEVICE DIE

(71) Applicant: Texas Instruments Incorporated, Dallas, TX (US)

(72) Inventors: Fan He, Shanghai (CN); Jie Chen, Plano, TX (US); Qinfang Shen, Dallas, TX (US); Rajen Manicon Murugan, Dallas, TX (US); Yu Yao, Shanghai (CN)

(21) Appl. No.: 19/042,837

(22) Filed: Jan. 31, 2025

(51) Int. Cl. H01L 25/16; H01L 21/56; H01L 23/00; H01L 23/31; H01L 23/495; H01L 23/538

(52) U.S. Cl. CPC H10W 90/00; H10W 70/417; H10W 70/611; H10W 70/65; H10W 74/016; H10W 74/114; H10W 70/429; H10W 72/01257; H10W 72/0198; H10W 72/07521; H10W 72/07533; H10W 72/252; H10W 72/255; H10W 72/29; H10W 72/536; H10W 72/5363; H10W 72/5445; H10W 72/552; H10W 72/5522; H10W 72/5524; H10W 72/5525; H10W 72/555; H10W 72/59; H10W 72/859; H10W 72/865; H10W 72/877; H10W 72/884; H10W 72/9445; H10W 90/722; H10W 90/728; H10W 90/736; H10W 90/738; H10W 90/752; H10W 90/754; H10W 90/756; H10W 90/758

(57) ABSTRACT

A described example includes: a semiconductor device die mounted to a die pad of a package substrate; a trench capacitor die mounted on and overlying a portion of a device side surface of the semiconductor device die, and including a trench capacitor formed in a semiconductor substrate; electrical connections that couple power bond pads of the trench capacitor die to power bond pads of the semiconductor device die and ground bond pads of the trench capacitor die to ground bond pads of the semiconductor device die, wherein the power bond pads include a first pair of bond pads and the ground bond pads include a second pair of bond pads, wherein the first pair of bond pads is interleaved with the second pair of bond pads in an alternating pattern; and mold compound covering the semiconductor device die, the trench capacitor semiconductor die, and a portion of the package substrate.

### TECHNICAL FIELD

This disclosure relates generally to electronic packaging, and more particularly to packaging semiconductor device dies including active devices such as transistors and associated passive dies, such as discrete trench capacitor dies, integrated in a microelectronic device package.

### BACKGROUND

The semiconductor industry continually develops packaged devices with more functionality in a single packaged microelectronic device, which can be referred to as “multi-chip modules” or “MCMs” or “system-in-package” or “SIP” devices. By providing a functional semiconductor device die and including the necessary passive components and sometimes multiple semiconductor device dies to form a commonly needed function in a single microelectronic device package, end users can be freed from the necessity of determining the values and types of various passive components that are needed to be combined with a semiconductor device die so as to perform the common functions. Further, integrating these devices into a single microelectronic device package, the system board area needed to implement the common function is reduced. Example applications include amplifiers, sensors, power supplies, AC-DC power converters, DC-DC power converters, battery chargers, and power controllers. In automotive systems, amplifiers that provide amplified signals while powered by a battery or alternator power source are often needed. A Class D amplifier device may include a switching FET amplifier implemented on a semiconductor device die, such as a one or more pairs of power transistors and/or corresponding power transistor gate drivers, along with various passive components such as capacitors, resistors, and inductors, to form a complete amplifier solution. In a particular example application, a Class D amplifier is configured as an audio amplifier. Since audio systems often have multiple loudspeakers, audio amplifiers can include two or four channels, each channel configured for sourcing audio signals for one of the loudspeakers.

The passive components used in system-in-package devices can include capacitors, which can have two terminals. Some capacitors can be ceramic capacitors. These two terminal passive components can be mounted near the semiconductor device die on a package substrate, and conductive traces on the package substrate can couple the devices together. One example application for a capacitor is an application for a bypass or “decoupling” capacitor, which can be coupled between a voltage supply terminal coupled to a semiconductor device and a ground terminal coupled to the semiconductor device. By coupling a capacitor in this manner, high frequency or “AC” noise that can occur due to rapid switching transistor operations within the semiconductor device die is filtered from the power terminal and from the ground terminal, which prevents the unwanted AC noise from adversely impacting the circuit operation of other devices in the system coupled to the power supply, and/or from entering the output signals of the system.

Discrete bypass capacitors placed as passive components on circuit board traces can create performance and reliability issues. In one approach bypass capacitors are placed on a system board near a packaged semiconductor device. However, when passive components are coupled to the semiconductor devices as bypass capacitors using conductive traces on a system circuit board, a loop inductance forms. The bypass capacitor is series coupled between a trace coupled to the power supply voltage and a trace coupled to a ground potential, the traces form a loop inductance. A loop inductance is an antenna which can couple to switching noise, and in an undesirable fashion, can increase noise on the signal traces. Compensation for the loop inductance can require additional capacitor compensation in the form of relatively high value capacitors, which require yet more passive devices, increasing the board area used for the amplifier. Paths that have relatively high loop inductance act as antennas and may increase the noise in the system, which is in opposition to the purpose of using the bypass capacitor (which is used for AC noise decoupling), reducing the effectiveness of the bypass capacitor. In addition, system board area is increasingly limited as systems become ever smaller, increasing the demand that the passive components such as the bypass capacitors be placed within the microelectronic device package along with the associated semiconductor device dies.

In another prior approach a discrete capacitor device and one or more semiconductor dies can be mounted to a package substrate and packaged together in a single device package. However, loop inductance also is increased by the conductive traces used on the package substrate and by other conductors used within the microelectronic device package, such as multiple metal traces within the semiconductor device die coupling transistors in the semiconductor device die to bond pads, and including solder bumps or bond wires used to couple the bond pads of the semiconductor device die and the package substrate and then traces that couple the terminals of the capacitor. In some example applications, the benefit of the bypass capacitor can be reduced or even eliminated due to the increased loop inductance that results from these traces and wires, making the bypass capacitor of limited effectiveness at reducing the AC noise.

Thus, there is a continuing need for increasingly reliable and increased integration in providing bypass capacitors along with semiconductor device dies integrated into a microelectronic device package.

### SUMMARY

In a described example, an apparatus includes: a semiconductor device die mounted to a die pad on a device side surface of a package substrate, the semiconductor device die having a device side surface with bond pads facing away from the package substrate; a trench capacitor die mounted on the device side surface of the semiconductor device die and overlying a portion of the device side surface of the semiconductor device die, the trench capacitor die including a trench capacitor formed in a semiconductor substrate; electrical connections that couple power bond pads of the trench capacitor die to power bond pads of the semiconductor device die and that couple ground bond pads of the trench capacitor die to ground bond pads of the semiconductor device die, wherein the power bond pads of the trench capacitor die include a first pair of bond pads configured to be coupled to a power supply voltage and the ground bond pads of the trench capacitor die include a second pair of bond pads configured to be coupled to a ground potential, wherein the first pair of bond pads is interleaved with the second pair of bond pads in an alternating pattern; and mold compound covering the die pad, the semiconductor device die, the trench capacitor die, and a portion of the package substrate, the mold compound forming a body of a microelectronic device package, and terminals of the package substrate exposed from the mold compound forming terminals of the microelectronic device package.

An example microelectronic device package includes: a semiconductor device die mounted to a die pad on a device side surface of a leadframe, the semiconductor device die having a device side surface with bond pads facing away from the die pad of the leadframe; a trench capacitor die mounted and overlying a portion of the device side surface of the semiconductor device die; at least four wire bond connections coupling at least four bond pads of the trench capacitor die to corresponding bond pads of the semiconductor device die, the at least four wire bond connections comprising two pairs of interleaved wire bond connections, each of the two pairs comprising a wire bond connection configured to be coupled to a power bond pad and a wire bond connection configured to be coupled to a ground bond pad; and mold compound covering the semiconductor device die, the trench capacitor die and portions of the device side surface of the leadframe, the mold compound forming a body of a microelectronic device package, with portions of conductive leads of the leadframe exposed from the mold compound and forming terminals of the microelectronic device package.

In a described example method for forming an arrangement, the method includes: mounting a semiconductor die on the device mounting surface of a package substrate, the semiconductor die having conductor layers formed on a device side surface that are spaced by dielectric material and configured to carry a power supply voltage and a ground potential; mounting a trench capacitor die over the device side surface of the semiconductor die, the trench capacitor die having multiple bond pads configured to be coupled to the power supply voltage and multiple bond pads configured to be coupled to the ground potential, a trench capacitor in the trench capacitor die being coupled between the power supply voltage and ground potential; forming first electrical connections between the multiple bond pads of the trench capacitor die and the conductive layers configured to carry the power supply voltage and to carry the ground potential on the device side surface of the semiconductor die, wherein the multiple bond pads of the trench capacitor die further comprise a first pair of power bond pads configured to be coupled to a power supply voltage and a second pair of ground bond pads configured to be coupled to a ground potential, wherein the first pair of bond pads is interleaved with the second pair of bond pads in an alternating pattern; forming second electrical connections between bond pads of the semiconductor device die and conductive leads of the package substrate; and covering the semiconductor device die, the trench capacitor die, and portions of the device mounting surface of the package substrate with mold compound, the mold compound forming a body of a microelectronic device package, wherein portions of conductive leads of the package substrate are exposed from the mold compound to form terminals for the microelectronic device package.

### BRIEF DESCRIPTION OF THE DRAWINGS

FIGS. 1A-1B illustrate, in projection views, a top side and a board side surface of an example microelectronic device package.

FIG. 2 is a cross-sectional view of a microelectronic device package of an arrangement.

FIGS. 3A and 3B illustrate in two projection views a semiconductor wafer having semiconductor devices formed on, and an individual semiconductor device die taken from a wafer, respectively. FIG. 3C illustrates a trench capacitor die for use in an arrangement configured for wire bonding connections, while FIG. 3D illustrates a trench capacitor die for use in an arrangement configured for flip chip connections.

FIGS. 4A-4E illustrate, in a series of cross-sectional views, selected steps for a method for forming a microelectronic device package that is useful with the arrangements. FIG. 4F illustrates, in a further cross-sectional view, an alternative arrangement.

FIGS. 5A-5B illustrate, in a plan view and a close-up view, details of an example arrangement for use in a microelectronic device package.

FIG. 6 illustrates in a process flow diagram selected steps of an example process for forming an arrangement.

### DETAILED DESCRIPTION

In the drawings, corresponding numerals and symbols generally refer to corresponding parts unless otherwise indicated. The drawings are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device die” is used herein. A semiconductor device die can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor die can include passive devices such as resistors, inductors, filters, sensors, or active devices such as transistors. The semiconductor device die can be an integrated circuit with hundreds, or thousands of transistors coupled to form a functional circuit, for example a microprocessor or memory device.

In an example application for an arrangement, the semiconductor device die can include one or more Class D amplifiers that use switching metal-oxide-semiconductor (“MOS”) field-effect-transistors (“FETS”) or MOSFETS to selectively couple a switching node to a power supply (when a first or high side MOSFET is turned on) or to a ground potential (when a second or low side MOSFET is alternatively turned on). By rapidly alternatively switching the high side and low side MOSFETS on and off, a load coupled to the switching node can be supplied with current. In audio applications, the load can include a speaker, earphone or other audio output, and the switching operation of the MOSFETs is determined by an input analog audio signal or by an input digital audio signal. Gate driver circuitry receives an input signal, such as a digital or analog audio signal, and creates pulse width modulated signals needed to rapidly turn the high and low side MOSFETS on and off to amplify and output the audio signals to the loudspeakers.

In some example arrangements, the semiconductor device die is a complete amplifier for an audio system with multiple channels, for example two, four, or more output channels, for different speakers. The switching frequency used to operate the MOSFETS can be in the kilohertz or megahertz range. In an automotive application, switching frequencies above 1 MHz can be used to improve noise performance by avoiding the amplitude modulated (“AM”) radio spectrum, and thereby to prevent unwanted interference with an AM radio in the automobile.

The term “passive component die” is used herein. A passive component die is a passive component fabricated as a semiconductor die. For example, a passive component die can be a trench capacitor (or “TCAP”) die. A trench capacitor die can be formed in a semiconductor manufacturing facility on a wafer. The trench capacitor die can be formed by forming a well or tank in a semiconductor substrate configured as a bottom plate, forming a trench extending into the semiconductor substrate, depositing dielectric material into the trench, and forming conductive material such as doped polysilicon, metal conductors, or metal gate material over the dielectric material to form a top plate. Conductors are formed over the semiconductor substrate to form bond pads electrically coupled to the bottom plate and the top plate to complete the passive trench capacitor component. The wafer is singulated into individual dies, which are passive component dies. Other passive components including resistors, coils, inductors, diodes, and sensors can be formed as passive component dies and can be used in the arrangements. Trench capacitor dies provide relatively high value capacitances in a solid-state semiconductor device die with long lifetimes and reliable values over a range of temperatures and over many years of use. In contrast to ceramic capacitors, the value of a semiconductor trench capacitor die can remain stable throughout the product's life, reducing the need for calibration or circuit adjustments during the product's life.

In an example application for an arrangement, one or more trench capacitor dies are used and packaged with a Class D amplifier semiconductor device die and coupled to provide decoupling capacitor(s) between power and ground potentials. The decoupling or bypass trench capacitor(s) reduce AC noise caused by the operation of the switching MOSFETS from affecting the power traces in the system, which can impact other devices coupled to the power supply.

The term “microelectronic device package” is used herein. A microelectronic device package has at least one semiconductor device die electrically coupled to terminals and has a package body that protects and covers the semiconductor die. The microelectronic device package can include additional elements, in example arrangements an integrated passive component die is included. Other passive components such as capacitors, resistors, and inductors or coils can also be included. In some arrangements, multiple semiconductor device dies can be packaged together. For example, a power metal oxide semiconductor (MOS) field effect transistor (FET) semiconductor die, and a logic semiconductor device die (such as a gate driver die, or a power FET controller die) can be packaged together to form a single microelectronic device package.

The term “package substrate” is used herein. A package substrate is a substrate arranged to receive a semiconductor die and to support the semiconductor die in a completed semiconductor device package. Package substrates useful with the arrangements include multilayer package substrates, embedded trace substrates, molded interconnect substrates, leadframes including pre-molded leadframes, partially etched leadframes, and stamped or plated leadframes. Multilayer package substrates useful with the arrangements can have trace level conductors spaced by dielectric material in layers, and vertical connection layers that extend through the dielectric material between trace level conductors to form routing networks. Additional package substrates that can be used include conductive leadframes, which can be formed from copper, aluminum, stainless steel, steel, and alloys such as Alloy 42 and copper alloys. The leadframes can include a die pad with a die side surface for mounting a semiconductor die, and conductive leads arranged near and spaced from the die pad, the conductive leads are configured for coupling to bond pads on the semiconductor die. The package substrate has a board side surface opposite the device side surface. Semiconductor device dies can be mounted on the die pad of a leadframe with a backside surface on the die pad, and a device side surface facing away from the die pad. Some leadframes useful with the arrangements have a “downset” die pad where the die pad lies in a different plane than the leads and is spaced from the plane of the leads downward towards a board side surface. In an alternative, an “upset” die pad can be used where the die pad is in a horizontal plane spaced away from the horizontal plane the leads are in and upwards away from the board side surface.

When the leadframes and the semiconductor die are covered with mold compound to form a protective package body, the die pad can have a surface exposed from the mold compound to form a thermal pad for the packaged device. Downset leadframes can provide a thermal pad on a board side surface that can be mounted on and thermally coupled to a thermal path. Upset leadframes can have an exposed die pad on an upper surface of the packaged devices, providing a thermal path for dissipating heat from the packaged devices to the ambient environment. In a process for mounting the semiconductor device dies, leadframes can be provided in strips or arrays of unit devices. The conductive leadframes can be provided as a panel with strips or arrays of unit device portions in rows and columns. Semiconductor device dies can be placed on the die pads of the respective unit device portions within the strips or arrays. A semiconductor device die can be placed on a die pad for each packaged device and die attach or die adhesive can be used to mount the semiconductor dies to the leadframe die pads.

The term “build-up package substrate” is used herein. A build-up package substrate” is a multilayer package substrate that has multiple trace level conductor layers, and which has vertical connection layer conductors extending through the dielectric material between the trace level conductor layers. In an example arrangement, a build-up package substrate is formed in an additive process by plating a patterned conductor level and then covering the conductor with a layer of film dielectric material. The film dielectric material can be applied at an elevated temperature to soften the material, and a vacuum can be used to cause the film dielectric material to conform to the conductor layers underneath. The film dielectric material can then be thermally cured to harden the dielectric material. Multiple layers of the film dielectric material can be applied. Grinding can be performed on the cured dielectric material to expose portions of the layer of conductors. Additional plating layers can be formed to add additional levels of conductors, some of which are coupled to the prior trace level conductor layers by vertical connection layers, and additional film dielectric material can be deposited at each level and can cover the conductors. By using an additive or build up manufacturing approach, and by performing multiple plating steps, molding steps, and grinding steps, a build-up package substrate can be formed with an arbitrary number of layers. In an example arrangement, copper conductors are formed by plating, and a thermoplastic material can be used as the dielectric material. In a particular example, the dielectric film can be an epoxy-based build-up film commercially available as “Ajinomoto Build-up Film,” from Ajinomoto Co., Inc., of Tokyo, Japan.

In packaging microelectronic and semiconductor devices, mold compound may be used to partially cover a package substrate, to cover components, to cover a semiconductor die, and to cover the electrical connections from the semiconductor die to the package substrate. This molding process can be referred to as an “encapsulation” process, although some portions of the package substrates are not covered in the mold compound during encapsulation, for example terminals and leads are exposed from the mold compound. Encapsulation is often a compressive molding process, where thermoset mold compound such as resin epoxy can be used. A room temperature solid or powder mold compound can be heated to a liquid state and then molding can be performed by pressing the liquid mold compound into a mold through runners or channels. Transfer molding can be used. Compression molding can be used, where the units to be covered with mold compound are pressed into a two-part mold with mold compound to force the mold compound to fill the mold. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded together. When mold compound is formed over the components mounted to a device mounting surface of a package substrate, it may be referred to as an “overmolding” process.

After the molding process, the individual packaged microelectronic devices are cut from each other in a sawing operation by cutting through the mold compound and package substrate in saw streets formed between the devices. Portions of the package substrate leads are exposed from the mold compound package to form terminals for the microelectronic device packages.

The term “conductive post connect” is used herein. As used herein, a conductive post connect is a structure made of a conductive material, for example copper, and provides a connection between bond pads on a die and a package substrate. A package substrate, such as a lead frame, will have a conductive portion arranged to electrically and mechanically connect to the conductive post connect. Solder will be formed at the distal end of the conductive post connect. In an example, solder balls can be used to form a conductive post connect. A copper pillar bump is another example of a conductive post connect. The conductive post connect can also be a column, rectangle, or rail shape, and can have an oval, round, or rectangular cross section. In examples, the conductive post connects are circular or oval in cross section and extend away from the bond pads of a semiconductor die to a distal end with solder on the distal end for mounting. In examples, the conductive post connects can be arranged in parallel with additional conductive post connects to provide a low resistance path between the die and the package. In an example arrangement, a trench capacitor die is flip chip mounted to the device side surface of a semiconductor device die, and electrical connection between the trench capacitor die and the semiconductor device die is made using conductive post connects, which can be copper pillar bumps with solder on the distal end, or solder balls.

The term “scribe lane” is used herein. A scribe lane is a portion of semiconductor wafer between semiconductor dies. Sometimes in related literature the term “scribe street” or “scribe line” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The term “quad flat no-lead” (QFN) is used herein for a type of electronic device package. A QFN package has conductive leads that are coextensive with the sides of a molded package body, and the leads are on four sides. Alternative flat no-lead packages may have leads on two sides or only on one side. These can be referred to as “small outline no-lead” or SON packages. No-lead packaged electronic devices can be surface mounted to a board.

Leaded packages can be used with the arrangements. In leaded packages, leads extend away from the package body and are shaped to form terminals for soldering to a board. A dual in-line package (DIP) can be used with the arrangements. A small outline package (SOP) can be used with the arrangements. A small outline transistor (SOT) package is a leaded package that can be used with the arrangements. Leaded packages can be used with leads on two sides or on all four sides. Plastic leaded packages can be used. Ceramic leaded packages can also be used.

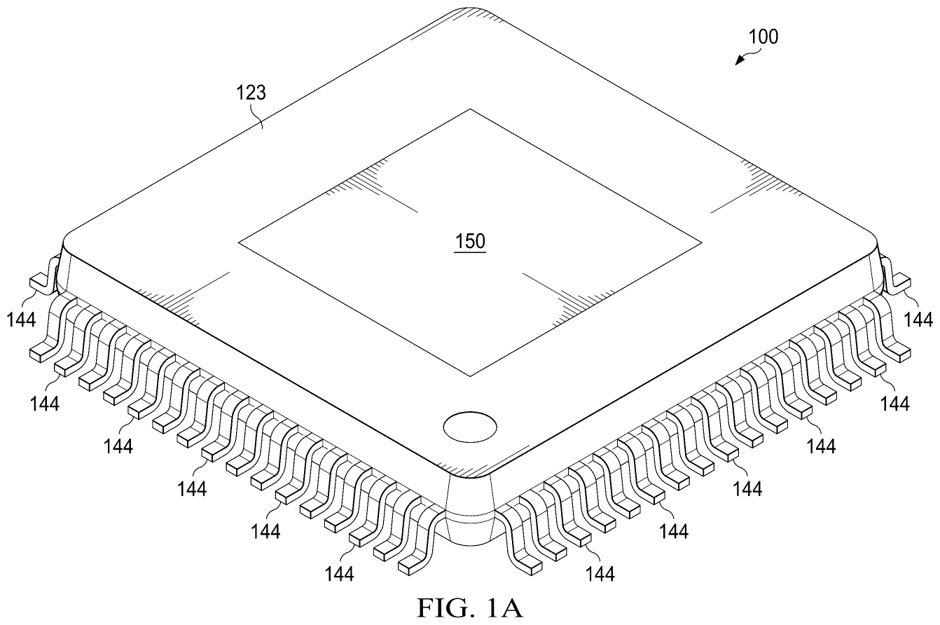

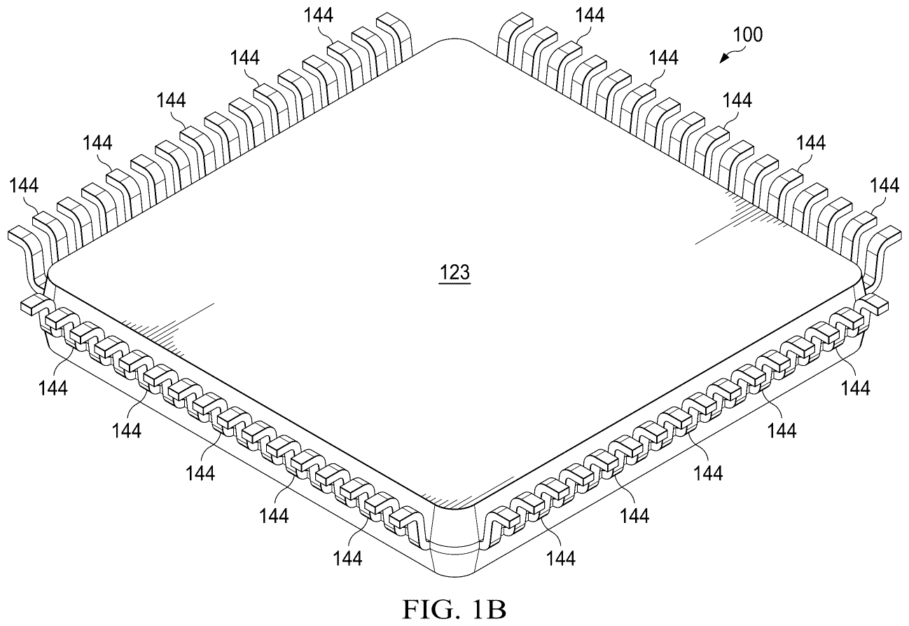

FIGS. 1A-1B are projection views of an example microelectronic device package that can be used with an arrangement. Microelectronic device package 100 has terminals 144 that extend from a package body formed of a mold compound 123. Microelectronic device package 100 has an exposed portion of a die pad 150 that, in this example, is on a top side surface that enhances thermal dissipation from the package. In an alternative example, the package can have an exposed portion of a die pad on a board side surface. The die pad on a board side surface can be mounted to a thermal path on a system board and provides enhanced thermal dissipation into a system board to transfer heat away from the microelectronic device package.

FIG. 1B is an additional projection view that illustrates the microelectronic device package 100 from a board side surface with terminals 144 extending from the mold compound 123. The terminals 144 are shaped and configured to be mounted to a system board, for example using surface mount technology (“SMT”) processes to mount the microelectronic device package 100.

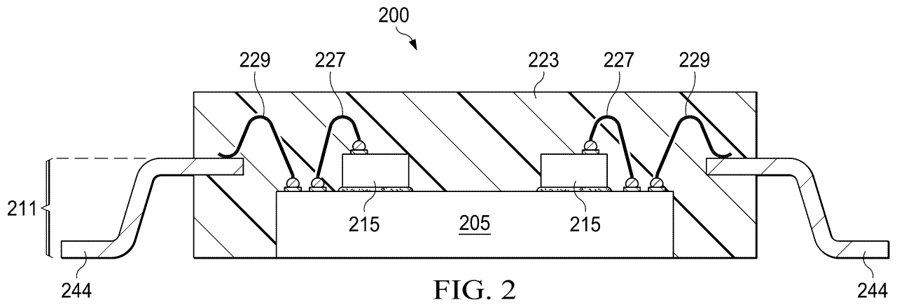

FIG. 2 illustrates, in a cross-sectional view, some details of an example arrangement. In FIG. 2, a microelectronic device package 200 includes a semiconductor device die 205 mounted to a package substate 211. The semiconductor device die 205 is mounted on a die pad (not shown for simplicity of illustration) of the package substrate 211 and is mounted with a device side surface facing away from the package substrate 211 (semiconductor device die 205 is shown facing upwards as the elements are oriented in FIG. 2.) In the illustrated example, TCAP semiconductor dies 215 are shown mounted face-up over the device side surface of the semiconductor device die 205. A first trench capacitor die and a second trench capacitor die are shown as TCAP dies 215 and positioned proximate to bond pads on the semiconductor device die 205. In an alternative arrangement, a single TCAP die 215 can be used. Electrical connections are formed between the TCAP die or dies and the semiconductor device die. In the illustrated example, wire bonds 227 electrically couple bond pads on the TCAP dies 215 to bond pads on the semiconductor device die 205. Wire bonds 229 further electrically couple additional bond pads on the semiconductor device die 205 to leads 244 of the package substrate 211, which can be a conductive leadframe, and in a more particular example, can be a copper or copper plated leadframe.

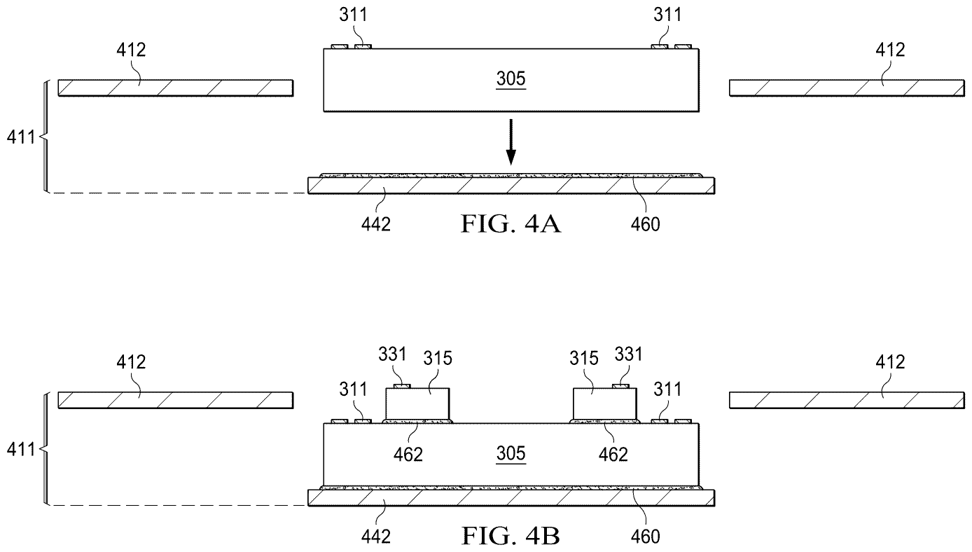

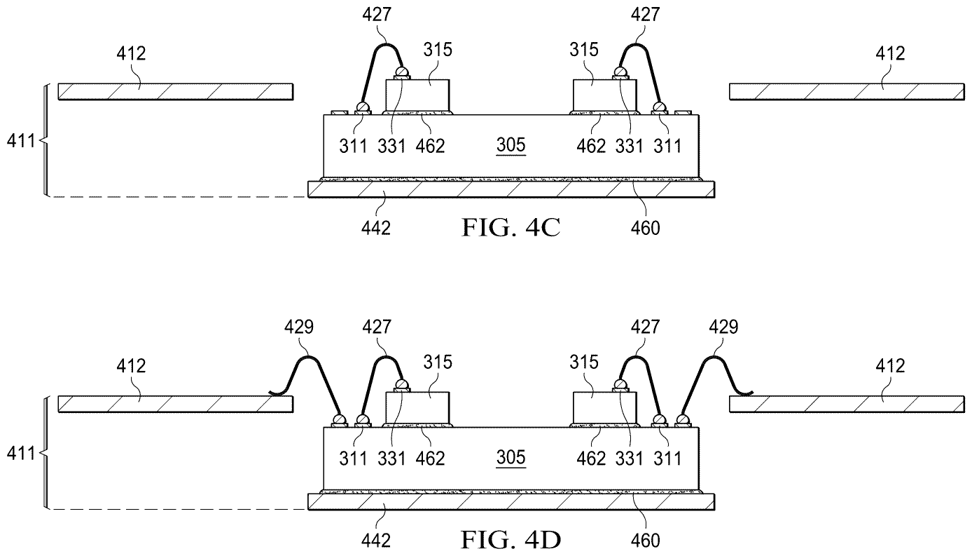

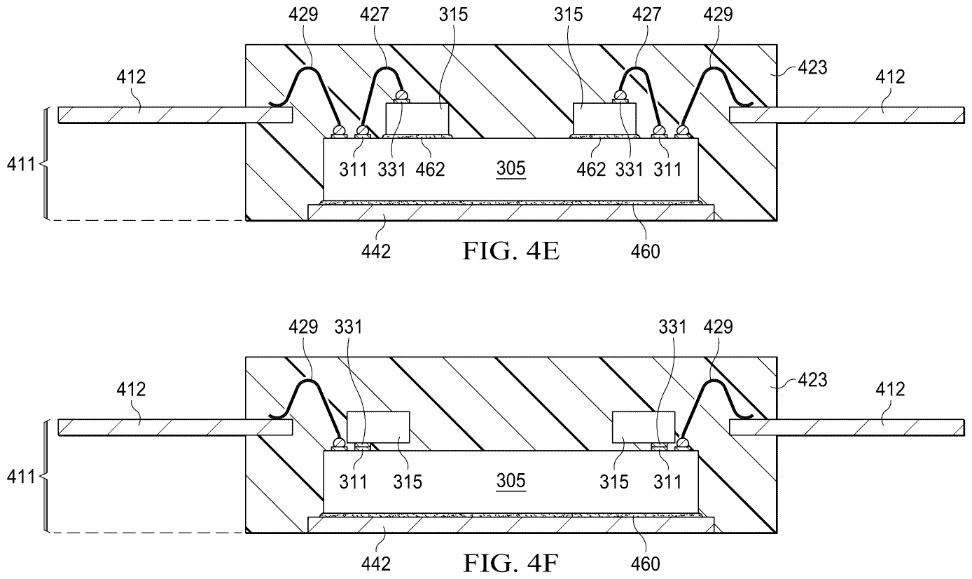

The example arrangement in FIG. 2 uses wire bond connections from the TCAP dies 215 to the semiconductor device die 205. In an alternative arrangement (see, for example, FIG. 4F below) the TCAP dies 215 can be flip chip mounted to the semiconductor device die, using conductive post connects, such as copper pillar bumps or solder bumps, to make a vertical connection between bond pads on the TCAP dies and the corresponding bond pads on the semiconductor device die. An advantage of the flip chip arrangements is that the short connection path that results between the TCAP dies (or alternatively, a single TCAP die) and the semiconductor device die inherently reduces the loop inductance. However, a disadvantage of the flip chip arrangements (when compared to the wire bonded arrangements such as is shown in FIG. 2) is the increased cost of manufacturing the TCAP dies. Flip chip processing requires wafer bumping to form conductive post connects, such as copper pilar bumps, and increased costs in assembly (compared to face up mounting and wire bond connections).

In an example arrangement, the semiconductor device die 205 can include switching MOSFET transistors (not visible in the illustrations), such as a high side driver MOSFET and a low side driver MOSFET coupled to a switching node output that can be operated to alternatively turn on and off to provide an output voltage. In one example, the semiconductor device die 205 can include multiple Class D amplifiers. TCAP dies 215 include trench capacitors. In an example, silicon TCAP dies are used.

In the arrangements, the bond wires 227 couple bond pads of the TCAP dies to bond pads of the semiconductor device die 205 that are also coupled to upper-level metal traces formed on the semiconductor device die 205. The trench capacitor dies are electrically coupled as bypass capacitors between traces configured to carry a positive (or negative) power voltage and a ground potential. The bond wires 227 couple the bond pads of the TCAP dies 215 to bond pads of the semiconductor device die 205. The bond pads on the TCAP dies 215 are configured to be coupled to power and ground potentials.

While in the illustrated examples, two TCAP dies are shown, in alternative arrangements, more or fewer TCAP dies can be used. A single TCAP die can be used, while in additional arrangements, more than two TCAP dies can be used. In the arrangements, bond pads on the TCAP dies, whether wire bonded to connect to the semiconductor device die, or flip chip mounted to the semiconductor device die, include multiple power and ground bond pads that are arranged in an alternating fashion to increase the mutual inductance between the power and ground paths. Additionally, in the arrangements, power and ground traces on the semiconductor device die can include portions that extend the power and ground paths in parallel and are placed in proximity to one another to further increase the mutual inductance, which also reduces the loop inductance.

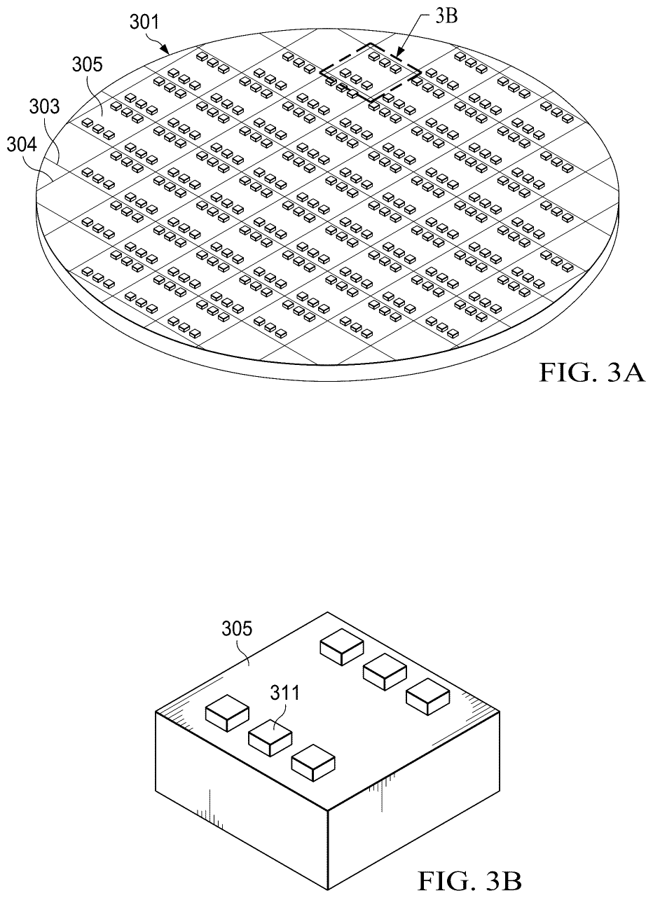

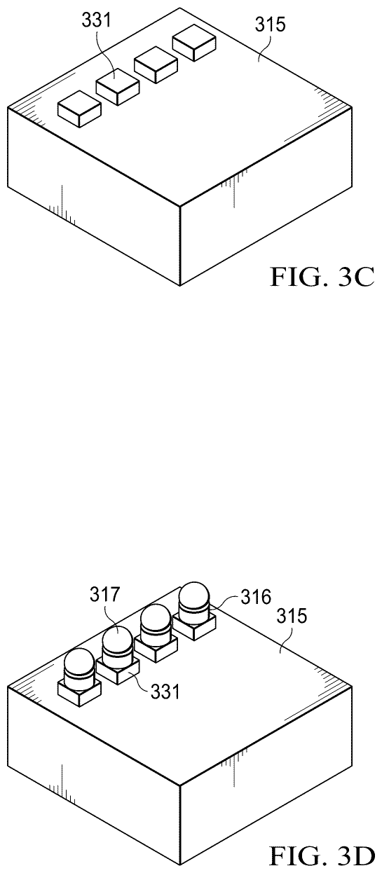

FIGS. 3A-3B illustrate, in projection views, a semiconductor wafer and an individual semiconductor device die taken from the semiconductor wafer, the individual semiconductor device die is arranged for wire bonding. FIG. 3C illustrates, in another projection view, a TCAP die arranged for wire bonding that can be used in an arrangement. In the arrangements, a semiconductor device die ready for mounting can be formed in a wafer fabrication facility. After transistors or other devices are formed in the semiconductor substrate, the devices with the semiconductor device dies can be connected to form circuitry by using multiple levels of conductors formed in dielectric layers over the substrate. Aluminum or copper conductors can be used, copper is increasingly used. Damascene processes including plating and chemical mechanical polishing can be used to form networks using multiple levels of conductors spaced by dielectric materials. The conductors can be vertically connected by conductive vias that extend through intervening levels of dielectric material. By connecting the multiple levels of metal together and coupling the lower levels of metal to the transistors or other devices formed in the semiconductor substrate, complex functional circuits can be formed. In the arrangements, upper-level conductor traces in the semiconductor device dies are configured to carry power potentials or ground potentials. By connecting bond pads to the power and ground conducive traces, and by electrically connecting the TCAP dies to the power and ground conductive traces, bypass capacitor electrical connections can be made. In example arrangements, wire bonding is used to connect the TCAP dies to the power and ground traces, to form the bypass circuit. In additional arrangements, flip chip mounting connects the TCAP dies to the semiconductor device die.

In FIG. 3A, an example semiconductor wafer 301 is shown with an array of semiconductor device dies 305 formed in rows and columns on a surface. The semiconductor device dies 305 can be formed using processes in a semiconductor manufacturing facility, including ion implantation, doping, anneals, oxidation, dielectric and metal deposition, photolithography, pattern, etch, photoresist stripping, chemical mechanical polishing (CMP), electroplating, and other processes for making semiconductor devices. Scribe lanes 303 and 304, which are perpendicular to one another, and which run in parallel groups across the semiconductor wafer 301, separate the rows and columns of the completed semiconductor dies 305, and provide defined areas for dicing the wafer 301 in a singulation operation, to separate the semiconductor device dies 305 from one another.

FIG. 3B illustrates a single semiconductor device die 305, with bond pads 311 formed on a device side surface. Bond pads 311 are conductive pads that are electrically coupled by conductors to devices (not shown) including transistors and circuitry formed in the semiconductor device die 305. The semiconductor device dies 305 are then separated by a dicing process, or are singulated, by cutting the semiconductor wafer 301 along the scribe lanes 303, 304 (see FIG. 3A). Example dicing processes include by use of a dicing saw, laser dicing, or plasma dicing.

FIG. 3C illustrates, in another projection view, an example TCAP die 315 that can be formed in another semiconductor fabrication process. However, in additional alternative arrangements a passive component die used in an arrangement can be a resistor, an inductor, a coil, a diode, or a sensor. TCAP die 315 will be mounted to a semiconductor device die (see 305 in FIG. 3B, for example) on a device side surface. Accordingly, the TCAP die 315 has bond pads 331 on a device side surface that are arranged to be connected to corresponding bond pads on the semiconductor device die. The TCAP die 315 is a semiconductor die and can be formed in a semiconductor manufacturing process on a wafer scale, using processes similar to the processes used to fabricate semiconductor device dies 305 on the wafer 301. However, due to the relatively simple devices formed within the TCAP die 315, the TCAP die can be smaller in area than the semiconductor device die 305. Further, the number of bond pads used on TCAP dies can be only those needed for coupling a capacitor, such as only power and ground bond pads when used in a bypass or decoupling configuration. In FIG. 3C, for example, the TCAP die 315 has only four bond pads 331, arranged in alternating pairs, for making power and ground connections. The bond pads 331 can be used for wire bonding. In an alternative arrangement, additional processing is performed to form conductive post-connects, for example copper pillar bumps, or solder balls, on the bond pads 331 in a wafer bumping operation. The bumped dies can then be flip chip mounted to the semiconductor device dies.

FIG. 3D illustrates, in another projection view, a TCAP die 315 arranged for flip chip mounting. In FIG. 3D, the bond pads 331 have conductive post connects 316 extending away from the bond pads, and solder bumps 317 are disposed on the distal ends of the conductive post connects 316. In an example useful with the arrangements, the conductive post connects 316 can be copper or copper alloy, and the conductive post connect 316 with the solder bumps 317 can be copper pillar bumps. Other conductive materials can be used for the conductive post connects such as gold. The conductive post connects 316 and the solder bumps 317 can be replaced by solder balls in an alternative arrangement.

The conductive post connects 316 form vertical connections for use in flip chip mounting the trench capacitor die 315 to a semiconductor device die. In contrast to a face up wire bonded arrangement, a flip chip mounting has the device side of the trench capacitor die 315 positioned facing the bond pads on the semiconductor device die, the components are brought into contact and a thermal reflow process uses the solder 317 at the distal ends of the conductive post connects 316 to form solder joints to the bond pads of the semiconductor device die. The flip chip arrangements, such as shown in FIG. 4F, have a shorter path from the trench capacitor die to the semiconductor device die (when compared to a wire bond connection). The shorter path can result in a lower loop inductance. However, the use of flip chip mounted trench capacitor dies increases costs when compared to the wire bonded arrangements. Wafer bumping of the trench capacitor dies to form the conductive post connects 316 and the solder bumps 317 adds costs over a trench capacitor die prepared for wire bonding.

FIGS. 4A-4E illustrate, in a series of cross-sectional views, selected steps for an example method for forming example arrangements. In FIG. 4A, semiconductor device die 305 is shown being mounted to a die pad 442 of a package substrate 411, which in the illustrated example is a downset type leadframe with die pad 442 that lies in a different plane (a horizontal plane as the elements are oriented in FIG. 4A) than the leads 412. Use of a downset leadframe allows for an exposed die pad on a surface of the finished microelectronic device packages which allows for thermal dissipation from the semiconductor device die such as 305 when in operation. Use of the downset leadframe also increases the vertical space available to mount devices on the device side of the leadframe, keeping the overall thickness of the finished microelectronic device package relatively thin. The semiconductor device die 305 is shown being attached to the die pad 442 using a die attach material 460, which can be a die attach epoxy, and which can be an electrically conductive die attach epoxy, or a non-conductive die attach epoxy. The die attach epoxy is thermally conductive to enhance heat dissipation. In another approach, a die attach film can be used for die attach material 460, instead of a die attach epoxy. The semiconductor device die 305 has bond pads 311 facing away from the die pad 442 (facing upwards as the elements are arranged in FIG. 4A) and configured for wire bonding.

In FIG. 4B, the elements of FIG. 4A are shown following another process step. In the illustrated example, two TCAP dies 315 are shown mounted to the device side surface of the semiconductor die 305. In the arrangements, at least one TCAP die 315 is used and connected as a bypass capacitor, configured to be coupled between a positive voltage supply and a ground potential that are also connected to the semiconductor device die. In the illustrated examples, two TCAP dies are shown, however one or many TCAP dies can be used. In an advantage accrued by use of the illustrated examples, by using two TCAP dies 315, or alternatively by using more than two TCAP dies such as three or four TCAP dies 315, the size and thickness of the individual TCAP dies can be reduced (when compared to using a single TCAP die in the same bypass capacitor configuration), which enables use of a thinner overall microelectronic device package while incorporating the TCAP dies of the arrangements. In example arrangements, the TCAP dies 315 have a die thickness of about 190 microns. The thickness can vary. The TCAP die or TCAP dies 315 are positioned near an edge of the semiconductor device die 305 to facilitate making wire bond connections between bond pads 331 on the TCAP dies 315, and bond pads 311 on the semiconductor die 305. In the illustrated examples, the thickness of the TCAP die 315 was less than the thickness of a prior approach bypass capacitor, and use of the TCAP dies in the arrangements, with a die thickness of less than 200 microns, allowed the stacked devices including the TCAP dies and the semiconductor device dies to be packaged in a standard package thickness. The example TCAP dies of this thickness of less than about 200 microns have a capacitance of about 3.6 nano Farads (nF). Die attach material 462 can be used to mount the TCAP dies 315 to the device side surface of the semiconductor device die 305. In an example a die attach film (DAF) such as a non-conductive die attach film (NCDAF) can be used as the die attach material 462. In an alternative, a non-conductive die attach epoxy is used for die attach material 462. In an additional alternative, a conductive die attach epoxy can be used.

In FIG. 4C, the elements of FIG. 4B are shown after a first wire bonding process. Wire bonds 427 are shown formed between bond pads 331 in on the TCAP dies 315 and bond pads 311 on semiconductor device die 305 (also not visible in FIG. 4B but see bond pads 311 on semiconductor device die 305 in FIG. 3B). These wire bonds can be used to form electrical connections and advantageously, in the arrangements, to increase the mutual inductance between the power path and the ground path. In an example arrangement, the TCAP dies 315 have multiple bond pads configured to be coupled to a power supply and a ground potential that are arranged in an alternating or interleaved fashion. By placing multiple bond pads configured to be coupled to a power supply potential, and using additional multiple bond pads configured to be coupled to a ground potential, and by alternating the bond pad placements along a periphery of the TCAP die, the bond wires that are used to form wire bonds extending from the TCAP die to corresponding bond pads on the semiconductor device die also alternatively are configured to carry a power supply potential and a ground potential. The spacing between the wire bonds and the bond pads is determined to be less than a predetermined distance so as to increase a mutual inductance between the wire bonds, which reduces the loop inductance along the path. The loop inductance is reduced by the mutual inductance. By increasing the mutual inductance, and by placing the TCAP dies on the semiconductor device die near the bond pads on the semiconductor device die to also control the bond wire lengths, the loop inductance can be substantially reduced by use of the arrangements.

In a useful process that can be used with the arrangements, a stand-off stitch on bump (“SSB”) bond wire bonding process can be used to form wire bonds 427. In an example SSB process, a wire bonding tool includes a spool or supply of bond wire and a movable capillary of a hard material, such as a ceramic, with a central opening that allows the bond wire to extend through the central opening. To begin a stand-off stitch on bump wire bond, the exposed end of the bond wire is melted to form a molten ball on the end of the bond wire, an electric arc or a flame can be used to form the molten ball. The molten ball is pressed onto a first bond pad to form a bump, ultrasonic energy and mechanical pressure can be used. The bond wire is cut or broken off at an edge of the bump. A stitch bond can later be formed on the bump. In an example, a second molten ball is formed on the newly exposed end of the bond wire. The capillary moves to a second bond pad where the wire bond connection is to be made and using mechanical and ultrasonic energy pushes the molten ball onto the bond pad. As the capillary moves away from the ball bond formed on the second bond pad, the bond wire is allowed to extend, and by moving the capillary in a prescribed manner while selectively clamping the bond wire, an arc or curved shaped wire bond is formed. The capillary returns to the first ball and makes a stitch bond on the first bump, to complete the SSB wire bond. As the capillary moves away from the stitch bond on the first bump, the bond wire is cut to complete the wire bond. A new exposed end of the bond wire is then ready for another bonding cycle. Die-to-die bonding is improved by this process because the bond pads are not directly “stitch” bonded (as in a conventional ball and stitch wire bonding process, which can damage the small features of the die bond pads.) Highly automated wire bonding tools can make many SSB wire bonds per second in an automated assembly facility.

FIG. 4D illustrates the elements shown in FIG. 4C after an additional processing step. In FIG. 4D, wire bonds 429 are shown formed between bond pads on the semiconductor device die 305 and leads 412 of the package substrate 411. The wire bonds 429 can be formed in an automated wire bonding machine using a thermosonic ball and stitch wire bonding process. In ball and stitch wire bonding, bond wire is extended through an opening in a capillary, which can be formed of a hard material such as a ceramic. To begin a new wire bonding cycle, the exposed end of the bond wire is exposed to a flame or electric arc to form a molten ball at the end of the bond wire. The capillary is moved over a bond pad and using heat, mechanical pressure and sonic vibration, the molten bond is pressed onto the bond pad to form a ball bond. As the capillary moves away from the bond pad, the bond wire is allowed to extend from the ball bond through the opening and by moving the capillary in a predetermined way, the wire bond can be shaped as an arc rising above the edge of the die. The capillary then moves over another conductive land such as a conductive lead of a leadframe. The capillary then again uses heat, mechanical pressure, and vibration to form a “stitch” bond on the conductive lead. The capillary then moves away from the stitch bond and using clamps or cutters attached to the capillary, breaks, or cuts the bond wire to form another exposed end. The bonding cycle can then begin again. Aluminum, copper, silver, gold, or alloys of these can be used as bond wire materials. Increasingly, palladium coated copper (“PCC”) wire is used. When copper or copper alloy bond wire is used, the wire bonder may have an anoxic environment, for instance by using nitrogen, to reduce corrosion of the wire and copper bond pads that might otherwise occur at the increased temperatures used in wire bonder tools.

FIG. 4E illustrates, in another cross section, the elements of FIG. 4D after a molding process is used to form a protective body of mold compound 423 around the semiconductor device die 305, the wire bonds 427, 429, as well as the TCAP dies 315. The mold compound 423 forms a protective body of a microelectronic device package 400. In an example process useful with the arrangements, the mold compound can be an electronic mold compound (“EMC”) of epoxy resin. Fillers can be used to increase the thermal dissipation of the mold compound. Transfer molding can be used. In an example transfer molding process, a mold chase supports the package substrate and the semiconductor device dies in a mold cavity. The mold compound can be provided as a room temperature solid as a puck, or as a powder. The mold compound is heated to a liquid state. The liquid is then forced through runners using mechanical pressure to fill the mold cavities and surround the devices. The mold compound is a thermoset material that sets and is allowed to further cure.

Once the molding process is complete, the devices can be finished in a trim and form process. The devices are singulated by sawing through the package substrate in saw streets between the devices and sawing through any mold compound that remains between devices. The leads are trimmed and formed to complete terminals for the microelectronic device packages, for example see microelectronic device package 200 in FIG. 2.

FIG. 4F illustrates, in an additional cross-sectional view, an alternative arrangement. In FIG. 4F, the TCAP dies 315 are shown flip chip mounted to the device side surface of the semiconductor device die 305. In this alternative approach, the electrical connections between the TCAP dies and the semiconductor device die are flip chip connections. Conductive post-connects, such as copper pillar bumps, or solder balls or bumps, are used to connect the bond pads 331 of the TCAP dies to the bond pads 311 of the semiconductor device die 305. By placing the TCAP dies 315 close to the transistors within the semiconductor device die 305 that need bypass capacitors, the loop inductance of the path can be made inherently smaller, as the path length is reduced (when compared to the wire bonded option). However, the cost of the flip chip arrangement is increased when compared to the wire bonded arrangements of FIG. 2, FIGS. 4A-4E. In a simulation, a similar reduction in loop inductance was achieved using the arrangement of FIG. 4E and by using the arrangement of FIG. 4F. The arrangements include the use of multiple bond pads on the TCAP die or dies that are configured to connect to power and ground, the power bond pads that are configured to connect to the power are interleaved with the ground bond pads configured to connect to ground, and are placed spaced apart by a space less than a predetermined distance to increase the mutual inductance.

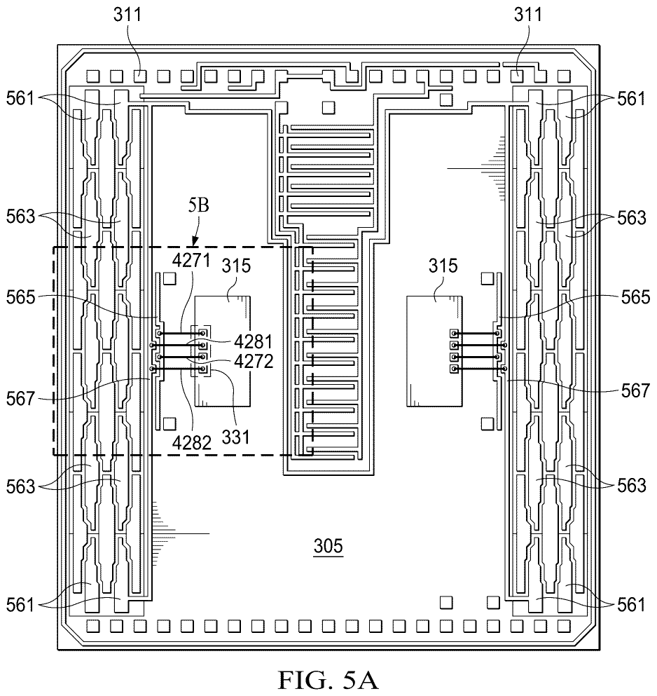

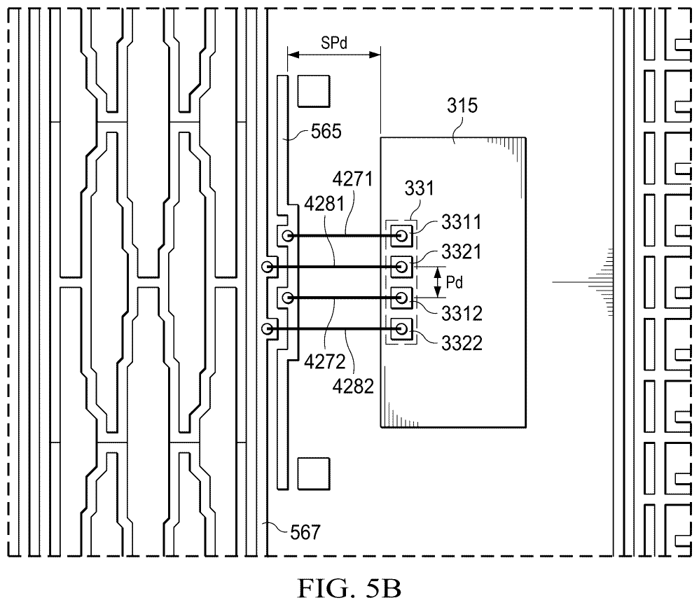

FIGS. 5A-5B illustrate in a plan view and a close-up view the bond pads, wire bonds and upper-level metallization patterns of a semiconductor device die and TCAP dies mounted in an example arrangement using wire bond electrical connections. Although two TCAP dies 315 are shown in this illustrated example, in an alternative arrangement, a single TCAP die 315 can be used, or more than two TCAP dies can be used to form additional alternative arrangements.

In FIG. 5A, the illustration is a plan view taken from the device side surface of semiconductor device die 305. Bond pads 311 are shown formed around the periphery of the semiconductor device die 305 and are configured to be used for wire bond connections to a lead of a package substrate (see, for example, wire bonds 429 in FIG. 4E between the semiconductor device die 305 and the leads 412.) Two TCAP dies 315 are shown mounted over the device side surface of the semiconductor die 305 spaced apart from one another and, in this illustrated example, symmetrically placed over opposite sides of the semiconductor device die 305 and are positioned proximate to upper-level metal traces 565 and 567. These traces 565 and 567 are configured to carry power supply potentials (567) and ground potentials (565) along sides of the semiconductor device die 305 and can be coupled to the larger traces 561 (for power supply potential) and 563 (for ground potential) in the upper-level metal traces for semiconductor device die 305. The TCAP dies 315 are connected to the conductor portions 567 (for power) and 565 (for ground) by four wire bonds 4271, 4272, 4281, and 4282. The upper-level metal trace portions 565, 567 are shown placed in close proximity to one another and running in parallel. In an advantage of the arrangements, these upper-level metal traces that are configured to carry power and ground potentials are configured to increase the mutual inductance between the traces that are carrying power and ground, so as to further reduce the loop inductance. The wire bonds 4271, 4272, 4281, and 4282 that are configured to couple the TCAP dies 315 to the upper level metal trace portions 565, 567 are shown placed in parallel to one another and in close proximity to one another in alternating pairs, a first pair of wire bonds 4271, 4272 couples to ground bond pads on the semiconductor device die 305, and a second pair of wire bonds 4281, 4282 couples to different power bond pads on the semiconductor device die, the two pairs of wire bonds couple to ground and power bond pads and are interleaved in an alternating pattern and are placed in parallel to one another to further increase the mutual inductance between the power and ground paths. In the arrangements, the TCAP dies 315 have at least two pairs of bond pads for carrying power and ground, although more bond pads, and more wire bonds, can be used.

FIG. 5B illustrates, in a close-up view, a portion of the semiconductor device die 305 and the TCAP die 315 in the circled portion of FIG. 5A. In FIG. 5B, the portion labeled “5B” in FIG. 5A is shown in more detail. TCAP die 315 is shown mounted over the device side of the semiconductor device die with bond pads 331 arranged along one side of the TCAP die 315. The trench capacitor die bond pads (see the oval area numbered 331 in FIG. 5A) are individually identified as 3311, 3312, 3321, and 3322 in FIG. 5B. The trench capacitor die bond pads are arranged in two pairs, 3311 and 3312 are power bond pads configured to be coupled to a positive power supply, while bond pads 3321 and 3322 are ground bond pads configured to be coupled to a ground potential, so that a trench capacitor formed within the TCAP die 315 is coupled as a bypass capacitor between power and ground. While the TCAP die 315 can be a trench capacitor, other semiconductor capacitor types can be used. The pairs of bond pads 3311, 3312, 3321, and 3322 are arranged in an interleaved fashion so that the power bond pads configured to be coupled to the positive voltage supply and the ground bond pads configured to be coupled to a ground potential alternate along the column of bond pads within the oval shape 331. A spacing distance labeled “Pd” (spacing distance is the pitch, the space between pads, plus half the pad width) is determined that is less than a maximum spacing distance in order to increase the mutual inductance between the wire bonds (4271, 4272, 4281, 4282) and the bond pads 3311, 3312, 3321, 3322 that are coupled to carry power and ground. In an example arrangement the spacing distance Pd is less than or equal to about 103 microns. Design rules for the process, the bond pads, and the wire bonding processes being used may also impose a minimum spacing distance, in forming an arrangement the pitch spacing distance Pd is chosen to increase the mutual inductance by reducing the spacing distance Pd. The wire bonds and the bond pads have a minimum spacing requirement between them to avoid inadvertent shorting due to a wire sweep effect during molding, and to keep the wire bonding process free from inadvertent shorts during ball bond and bond wire placement, but in the arrangements these elements are placed within the illustrated pitch distance Pd to enhance mutual inductance. The wire bonds 4271, 4272, 4281, 4282 are also kept relatively short in length by spacing the edge of the TCAP die 315 that faces the bond pads on the semiconductor die 305 within a predetermined maximum distance of the bond pads on the semiconductor die 305, in an example arrangement this distance was about 340 microns, the minimum spacing allowed from the bond pads on the semiconductor device die to the closest edge of the TCAP dies. This spacing distance determines the length of the wire bonds, which is proportional to the loop inductance, so reducing this spacing distance (labeled “SPd”) further reduces the loop inductance. In the alternative arrangement of FIG. 4F, where a flip chip mounting is used for the TCAP dies, the wire bonds 4271, 4281, 4272, 4282 are not present, further reducing the loop inductance. In that example use of the alternating bond pads for power and ground connection still increases the mutual inductance between the power and ground paths, resulting in a reduction in loop inductance for the flip chip arrangements (when compared to prior approaches formed without the use of the arrangements).

In the arrangements, advantageous positioning of the bond pads 331 of the TCAP dies with respect to corresponding bond pads on the semiconductor die 305 is used, along with advantageous arrangement of wire bonds or flip chip connections, to increase the mutual inductance between the power and ground signals, and therefore reduce the loop inductance. Further, in a wire bond example, by placing the TCAP dies proximate to the bond pads 311 of the semiconductor die, the length of the wire bonds 4271, 4272, 4281, 4282 can be determined and controlled, by making this distance shorter, the loop inductance can also be lowered.

In the arrangements, the bond pads on the TCAP dies configured for power connection and the bond pads configured for ground connections are interleaved, to increase mutual inductance. For example, in the arrangements, for each TCAP die 315 there are at least two pairs of bond pads 331, two of these bond pads are configured to be coupled to the power supply voltage, and two of these bond pads are configured to be coupled to the ground potential, and these bond pads are interleaved, or alternate with one another along a column or row, and are placed along a side of the TCAP die configured for wire bond connection to the corresponding bond pads on the semiconductor device die. By positioning the bond pads 331 adjacent to one another and in an interleaved fashion, mutual inductance can be increased between the signals (power supply and ground potentials) that are to be coupled. Further, in a wire bond arrangement, by interleaving the wire bonds, which are also placed adjacent to one another in the interleaved fashion, at least four wire bonds are used in the arrangements to further increase the mutual inductance. Increased mutual inductance reduces the loop inductance.

In FIG. 5B, the wire bonds are labeled 4271, 4272 for the power wire bonds that connect the positive power supply to the TCAP die 315, and are labeled 4281, 4282 for the ground wire bonds that connect the ground potential to the TCAP die. In alternative arrangements, additional bond pads and wire bonds can be used to carry the positive supply voltage and the ground potential.

In the arrangements, the elements are specifically arranged to further increase mutual inductance, and thereby reduce the loop inductance, of a path including a trench capacitor coupled between a power supply and a ground potential. While design rule requirements for minimum spacing between pads and between elements must be met, the spacings used are selected to increase mutual inductance, and to reduce loop inductance. For example, the spacing distance (labeled SPd in FIG. 5B) from the edge of the TCAP dies to the bond pads on the semiconductor device die 305 is selected to keep the wire bond lengths relatively short, which reduces the loop inductance (when compared to longer distances with longer wire bonds). Further, the wire bonds are placed in the interleaved fashion described above, in parallel to one another and proximal to one another, to further increase the mutual inductance between the power and ground paths to and from the series connected bypass capacitors within the trench capacitor dies 315. The bond pads and the wire bonds have a pitch distance Pd of less about 103 microns in an example arrangement, while the wire bonds must be spaced far enough apart to prevent shorts due to “wire sweep” during the molding process, but yet are kept close enough to one another to cause an increase in the mutual inductance.

In an evaluation of an example arrangement, simulations were performed to compare a loop inductance obtained using a prior approach to the loop inductance obtained by the use of the arrangements. A loop inductance of a semiconductor die in a device package with an external bypass capacitor (a prior approach) was compared to the loop inductance obtained using the arrangements. For a wire bond connection example arrangement, the loop inductance using the trench capacitor dies overlying the semiconductor device die as described above was determined to be about 0.7 nH, an over 75% reduction (from a prior approach that used a ceramic bypass capacitor component mounted on a PCB proximal to a packaged device.) In a further simulation, a similar reduction of loop inductance was obtained using a flip chip TCAP die assembly. Use of the wire bond connections with trench capacitor dies positioned and arranged as described above was also compared to use of a single flip chip mounted trench capacitor die formed without the interleaved bond pads of the arrangements, and again the use of the arrangements substantially decreased the loop inductance (to about 0.5-0.7 nH from a 6-8 nanohenry (nH) value obtained in simulation for the prior approach). By use of the arrangements a more effective solution is obtained with substantially reduced loop inductance.

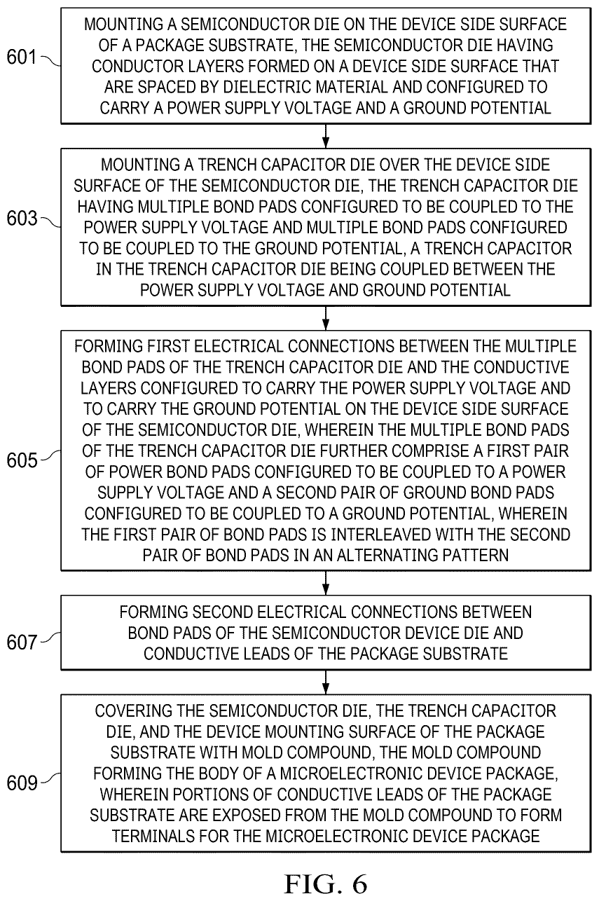

FIG. 6 illustrates, in a flow diagram, selected steps for forming a microelectronic device package including an arrangement. In FIG. 6, the method begins at step 601, by mounting a semiconductor die on the device mounting surface of a package substrate, the semiconductor die having conductor layers formed on a device side surface that are spaced by dielectric material and configured to carry a power supply voltage and a ground potential. (See, for example, FIG. 4A, where semiconductor device die 305 is mounted to the die pad 442 of a package substrate 411).

At step 603, the method continues by mounting a trench capacitor die over the device side surface of the semiconductor die, the trench capacitor die having multiple bond pads configured to be coupled to the power supply voltage and multiple bond pads configured to be coupled to the ground potential, a trench capacitor in the trench capacitor die being coupled between the power supply voltage and ground potential (See, for example, either of TCAP dies 315 mounted on semiconductor device die 305 in FIG. 4B).

At step 607, the method continues by forming first electrical connections between the multiple bond pads of the trench capacitor die and the conductive layers configured to carry the power supply voltage and to carry the ground potential on the device side surface of the semiconductor die, wherein the multiple bond pads of the trench capacitor die further comprise a first pair of power bond pads configured to be coupled to a power supply voltage and a second pair of ground bond pads configured to be coupled to a ground potential, wherein the first pair of bond pads is interleaved with the second pair of bond pads in an alternating pattern (See, for example, FIG. 4C, where wire bonds 427 are shown formed to couple bond pads 331 on TCAP dies 315 to the bond pads 311 on semiconductor die 305. See also FIG. 4F, where in a flip chip example, the electrical connections are made by conductive post-connects formed on the TCAP die and used for solder connections between the bond pads on the TCAP die and the bond pads on the semiconductor device die, and see FIG. 5B, where the bond pads 3311, 3321,3312, 3322 are shown in the alternating pattern).

The method continues to step 607 by forming second electrical connections between bond pads of the semiconductor device die and conductive leads of the package substrate. (See, for example, FIG. 4D or FIG. 4F, where bond wires 429 are shown coupling the semiconductor die 305 to the conductive leads 412 of the package substrate 411.)

At step 609, the method continues with a molding step to form microelectronic device packages by covering the semiconductor die, the trench capacitor die, and portions of the device mounting surface of the package substrate with mold compound, the mold compound forming a body of a microelectronic device package, wherein portions of the conductive leads of the package substrate are exposed from the mold compound to form terminals for the microelectronic device package. (See, for example, FIG. 4E, showing the formation of mold compound 423 over the elements, and portions of the conductive leads 412 exposed from the mold compound 423.)

In the example arrangements, a trench capacitor die or multiple trench capacitor dies are mounted to the device side surface of a semiconductor device die, and electrical connections are formed to couple the trench capacitor dies to bond pads on the semiconductor device die. In one example approach, wire bond connections are used. In another example approach, flip chip connections are used. The bond pads are configured to couple positive voltage supply and ground potential traces to the trench capacitor dies. The arrangement and spacing of the wire bonds and the placement of the bond pads on the trench capacitor die are designed to increase mutual inductance between conductors carrying the positive voltage supply and the ground potential, which reduces the loop inductance of the signal path including the trench capacitors. In a wire bond example arrangement, the trench capacitor dies are positioned over the device side surface of the semiconductor die close to the bond pad connections on the semiconductor device die for the power and ground wire bonds, to shorten the wire lengths of the wire bonds and further reduce the loop inductance. In additional alternative arrangements, the trench capacitor die or dies are flip chip mounted to the semiconductor device die and placed close to the transistors within the semiconductor device die that require a bypass circuit, to further reduce loop inductance. Additional passive component dies can be mounted including another component type formed in a die, such as a resistor, inductor, diode, or sensor device. In further alternative arrangements, two or more trench capacitor dies can be mounted to the semiconductor device die, for example four trench capacitor dies can be used. By using multiple trench capacitor dies, the sizes of the trench capacitor dies used in the arrangement can be reduced (compared to using a single trench capacitor die) and in an example arrangement with two trench capacitor dies, no change to existing package sizes was needed to include the multiple trench capacitor dies in the example arrangements.

The wire bond arrangements offer a reduction in cost over the flip chip arrangements, although both of these arrangements reduce the loop inductance obtained (when compared to a prior approach without use of the arrangements). The use of wire bond connections is economical and well established and allows for the placement of the bond pads and the wire bonds to increase the mutual inductance in the arrangements, reducing the loop inductance. Advantageously, in all the arrangements, the trench capacitor dies are placed over and within the area of the semiconductor device die, so that no additional area is needed on the package substrate to mount these devices together in a single microelectronic device package. In an example similar to the wire bonded arrangement of FIG. 4E, the TCAP dies have a thickness of about 190 microns, while the bond wire loop height was about 50 microns, allowing the TCAP dies to be incorporated into the package without changing the package thickness over a standard package thickness. The example TCAP dies each provided a trench capacitor of about 3.6 nano-Farads.

The use of the arrangements provides a microelectronic device package with a semiconductor device die and a trench capacitor die or multiple trench capacitor dies combined and mounted to a package substrate and covered with mold compound. Existing materials and assembly tools are used to form the arrangements. The arrangements are formed using existing methods, materials, and tooling for making the devices and implementation of the arrangements is cost effective.

Modifications are possible in the described examples, and other examples are possible, within the scope of the claims.

What is claimed is:

1. An apparatus, comprising:
a semiconductor device die mounted to a die pad of a package substrate, the semiconductor device die having a device side surface with bond pads facing away from the package substrate;
a trench capacitor die mounted on the device side surface of the semiconductor device die and overlying a portion of the device side surface of the semiconductor device die, the trench capacitor die comprising a trench capacitor formed in a semiconductor substrate;
electrical connections that couple power bond pads of the trench capacitor die to power bond pads of the semiconductor device die and that couple ground bond pads of the trench capacitor die to ground bond pads of the semiconductor device die, wherein the power bond pads of the trench capacitor die comprise a first pair of bond pads configured to be coupled to a power supply voltage and the ground bond pads of the trench capacitor die comprise a second pair of bond pads configured to be coupled to a ground potential, wherein the first pair of bond pads is interleaved with the second pair of bond pads in an alternating pattern; and
mold compound covering the die pad, the semiconductor device die, the trench capacitor die, and a portion of the package substrate, the mold compound forming a body of a microelectronic device package, and terminals of the package substrate exposed from the mold compound forming terminals of the microelectronic device package.

2. The apparatus of claim 1, wherein the trench capacitor die comprises a first trench capacitor die and further comprising at least a second trench capacitor die, and the trench capacitors within the first trench capacitor die and the second trench capacitor die are each coupled in a decoupling configuration.

3. The apparatus of claim 2, wherein the first and second trench capacitor dies are positioned over the device side surface of the semiconductor device die symmetrically and are positioned on opposite sides of the device side surface of the semiconductor device die.

4. The apparatus of claim 1, wherein the trench capacitor die is mounted with the power bond pads of the trench capacitor die facing away from the semiconductor device die, and wherein the electrical connections further comprise wire bond connections.

5. The apparatus of claim 4, wherein the wire bond connections between the trench capacitor die and the semiconductor device die further comprise stand-off stitch on bump wire bond connections.

6. The apparatus of claim 1, wherein the trench capacitor die is flip chip mounted to the semiconductor device die, and wherein the electrical connections are solder connections formed between conductive post connects on the trench capacitor die and the bond pads of the semiconductor device die.

7. The apparatus of claim 6, wherein the conductive post connects are copper pillar bumps.

8. The apparatus of claim 1, wherein the semiconductor device die further comprises conductive traces spaced by dielectric material on the device side surface, a first plurality of the conductive traces configured as power traces coupled to the power bond pads of the semiconductor device die, and a second plurality of the conductive traces coupled to the ground bond pads of the semiconductor device die, and a portion of the power traces is arranged spaced from and parallel to a portion of the ground traces.

9. The apparatus of claim 1, wherein the package substrate further comprises a conductive leadframe.

10. The apparatus of claim 1, wherein the package substrate further comprises a multilayer package substrate having trace level conductors spaced from one another by dielectric material, and vertical connection layer conductors extending through the dielectric material between the trace level conductors to selectively connect the trace level conductors.

11. The apparatus of claim 10, wherein the multilayer package substrate further comprises a build-up package substrate and the dielectric material comprises Ajinomoto Build-Up Film.

12. The apparatus of claim 1, wherein the package substrate further comprises one of a build-up package substrate, a leadframe, a partially etched leadframe, a premolded leadframe, or a molded interconnect substrate.

13. The apparatus of claim 1, and further comprising a first pair of wire bonds coupled between the first pair of bond pads and power bond pads on the semiconductor device die, and a second pair of wire bonds coupled between the second pair of bond pads and ground bond pads on the semiconductor device die.

14. The apparatus of claim 13, wherein the first pair of wire bonds coupled to the power bond pads and the second pair of wire bonds coupled to the ground bond pads are interleaved and are arranged in an alternating pattern.

15. The apparatus of claim 13, wherein a spacing distance between adjacent ones of the first pair of bond pads and the second pair of bond pads on the trench capacitor die is less than or equal to about 103 microns.

16. The apparatus of claim 1, wherein the trench capacitor die has four exterior edges and is positioned over the semiconductor device die so that a spacing distance from an edge of the trench capacitor die that is closest to a power bond pad on the semiconductor device die to the power bond pad is less than or equal to about 310 microns.

17. A microelectronic device package, comprising:
a semiconductor device die mounted to a die pad on a leadframe, the semiconductor device die having a device side surface with bond pads facing away from the die pad of the leadframe;
a trench capacitor die mounted on and overlying a portion of the device side surface of the semiconductor device die;
at least four wire bond connections coupling at least four bond pads of the trench capacitor die to corresponding bond pads of the semiconductor device die, the at least four wire bond connections comprising two pairs of interleaved wire bond connections, each of the two pairs comprising a wire bond connection configured to be coupled to a power bond pad and a wire bond connection configured to be coupled to a ground bond pad; and
mold compound covering the die pad, semiconductor device die, the trench capacitor die and portions of the leadframe, the mold compound forming a body of a microelectronic device package, with portions of conductive leads of the leadframe exposed from the mold compound and forming terminals of the microelectronic device package.

18. The microelectronic device package of claim 17 wherein the at least four bond pads of the trench capacitor die further comprise two pairs of interleaved bond pads, with a first one of the interleaved bond pads configured to be coupled to a power bond pad by a wire bond connection, and a second one of the interleaved bond pads configured to be coupled to a ground bond pad by another wire bond connection.

19. The microelectronic device package of claim 18 wherein the at least four bond pads of the trench capacitor die further comprise a pitch distance between adjacent ones of the at least four bond pads of less than about 103 microns.

20. The microelectronic device package of claim 19 wherein a spacing distance between an exterior edge of the trench capacitor die that is closest to the power bond pads of the semiconductor device die and the power bond pads on the semiconductor device die is less than about 310 microns.

21. The microelectronic device package of claim 17 wherein the trench capacitor die comprises a first trench capacitor die and further comprising a second trench capacitor die mounted on the device side surface of the semiconductor device die spaced from the first trench capacitor die, the first trench capacitor die and the second trench capacitor die each comprising a trench capacitor formed in a semiconductor substrate.

22. A method, comprising:
mounting a semiconductor die on a device mounting surface of a package substrate, the semiconductor die having conductor layers formed on a device side surface that are spaced by dielectric material and configured to carry a power supply voltage and a ground potential;
mounting a trench capacitor die over the device side surface of the semiconductor die, the trench capacitor die having multiple bond pads configured to be coupled to the power supply voltage and multiple bond pads configured to be coupled to the ground potential, a trench capacitor in the trench capacitor die being coupled between the power supply voltage and ground potential;
forming first electrical connections between the multiple bond pads of the trench capacitor die and the conductive layers configured to carry the power supply voltage and to the conductive layers configured to carry the ground potential on the device side surface of the semiconductor die, wherein the multiple bond pads of the trench capacitor die further comprise a first pair of power bond pads configured to be coupled to a power supply voltage and a second pair of ground bond pads configured to be coupled to a ground potential, wherein the first pair of bond pads is interleaved with the second pair of bond pads in an alternating pattern;
forming second electrical connections between bond pads of the semiconductor device die and conductive leads of the package substrate; and
covering the semiconductor device die, the trench capacitor die, and the device mounting surface of the package substrate with mold compound, the mold compound forming a body of a microelectronic device package, wherein portions of conductive leads of the package substrate are exposed from the mold compound to form terminals for the microelectronic device package.

23. The method of claim 22, wherein mounting the trench capacitor die comprises mounting a first trench capacitor die and further comprising mounting a second trench capacitor die over the device side surface of the semiconductor die spaced from the first trench capacitor die, the second trench capacitor die having multiple bond pads configured to be coupled to the power supply voltage and multiple bond pads configured to be coupled to the ground potential, a trench capacitor in the second trench capacitor die configured to ne coupled between the power supply voltage and ground potential as a decoupling capacitor.

24. The method of claim 22, wherein forming the first electrical connections further comprises forming wire bond connections between the multiple bond pads on the trench capacitor die and bond pads on the device side surface of the semiconductor die, and the wire bond connections are configured to be coupled to the power supply voltage or to the ground potential.

25. The method of claim 22 wherein forming the second electrical connections further comprises forming additional wire bond connections between the bond pads on the semiconductor die and conductive leads on the package substrate.

26. The method of claim 24, wherein forming the wire bond connections of the first electrical connections comprises forming alternating power wire bond connections and ground wire bond connections that extend in parallel between the bond pads of the trench capacitor die and the bond pads of the semiconductor die.

27. The method of claim 23, wherein the wire bond connections of the first electrical connections are spaced from one another at a pitch distance that is less than 103 microns from one bond wire to another bond wire.
